(19) United States
(12) Patent Application Publication
(10) Pub. No.: US 2016/0070643 A1
(43) Pub. Date: Mar. 10, 2016

(54) SYSTEM AND METHOD OF COUNTING PROGRAM/ERASE CYCLES

(71) Applicant: SANDISK TECHNOLOGIES INC., Plano, TX (US)

(72) Inventor: ZHENLEI SHEN, Milpitas, CA (US)

(73) Assignee: SANDISK TECHNOLOGIES INC.

(21) Appl. No.: 14/480,306

(22) Filed: Sep. 8, 2014

(51) Int. Cl. G06F 12/02; G11C 14/00

(52) U.S. Cl. CPC G06F 12/0246; G11C 14/0081; G06F 2212/7208; G06F 2212/7211

(57) ABSTRACT

A method includes, in a data storage device that includes a memory, detecting an operation associated with a block of the memory. The operation is associated with a program/erase cycle. The method further includes, responsive to detecting the operation, performing a comparison between a random number and at least one value of a set of values. The method includes selectively adjusting a value of a counter associated with the block based on the comparison.

### FIELD OF THE DISCLOSURE

The present disclosure is generally related to counting program/erase cycles.

### BACKGROUND

Non-volatile data storage devices, such as embedded memory devices (e.g., embedded MultiMedia Card (eMMC) devices) and removable memory devices (e.g., removable universal serial bus (USB) flash memory devices and other removable storage cards), have allowed for increased portability of data and software applications. Users of non-volatile data storage devices increasingly rely on the devices to store and provide rapid access to a large amount of data.

A data storage device may be associated with a write endurance, such as a number of program/erase (P/E) cycles that can be performed at storage elements of the memory device without impairing reliability of the storage elements. For example, after a large number of P/E cycles at a memory of the data storage device, stored data may become unreliable due to physical wear associated with the programming and erase operations. As a result, the data storage device may count P/E cycles for each block of the memory and may operate the memory so that wear is “distributed” approximately evenly among the blocks.

A data storage device may include counters for each block to count P/E cycles. The counters are sized to enable counting up to the write endurance limit for each block. For example, the data storage device may include multiple eight-bit counters for each block and may use the eight-bit counters to count every P/E cycle for each block. When a particular block (e.g., a hybrid block) may be used in multiple modes, such as a single-level cell (SLC) mode or a multi-level (MLC) mode, the data storage device may use two sets of two eight-bit counters (e.g., two eight-bit counters corresponding to the SLC mode and two eight-bit counters corresponding to the MLC mode) to track a total number of P/E cycles for the particular block. Thus, the data storage device may use multiple counters (e.g., 8-bit counters) to track the number of P/E cycles of a given block of the memory. Using multiple counters for each block increases a cost, size, and power consumption of the data storage device.

### SUMMARY

The present disclosure describes techniques for counting a number of program/erase (P/E) cycles at a data storage device using a reduced number of counters. For example, a statistical technique may be used whereby a value of a counter (associated with a block) is configured to be adjusted every Z P/E cycles (e.g., a probability of adjusting the value of the counter based on a given P/E cycle is 1/Z), where Z is a positive integer. To illustrate, the counter may be configured to track a number of P/E cycles associated with the block by selectively adjusting a value of the counter based on randomly generated numbers. For example, a random number may be generated to be constrained within a range and the generated random number may be compared to a set of one or more values to determine whether to adjust the value of the counter. A size of the range and/or a number of values included in the set of values may be selected such that the value of counter is (statistically) a fraction of the total number of P/E cycles. Thus, by adjusting the counter based on a random number, a size of the counter may be reduced as compared to a counter that is configured to be adjusted for every P/E cycle. Additionally, by selecting different sizes of the range and/or different values to be included in the set of values, different rates of counting P/E cycles may be realized. For example, a first rate of counting may count every M cycles for a multi-level cell (MLC) block and a second rate of counting may count every S cycles for a single-level cell (SLC) block, where M and S are different positive integers. Further, by changing the size of the range and/or the number of values included in the set of values, a single counter may be used to count a number of P/E cycles for a hybrid block (e.g., a block that can switch between operating as an MLC block and an SLC block).

### BRIEF DESCRIPTION OF THE DRAWINGS

FIG. 1 is a block diagram of a particular illustrative embodiment of a system including a data storage device configured to count program/erase cycles;

FIG. 2 is a flow diagram of a first illustrative embodiment of a method to count program/erase cycles;

FIG. 3 is a flow diagram of a second illustrative embodiment of a method to count program/erase cycles;

FIG. 4 is a flow diagram of a third illustrative embodiment of a method to count program/erase cycles;

FIG. 5 is a flow diagram of a fourth illustrative embodiment of a method to count program/erase cycles; and

FIG. 6 is a flow diagram of a fifth illustrative embodiment of a method to count program/erase cycles.

### DETAILED DESCRIPTION

Particular implementations of the present disclosure are described with reference to the drawings. In the description, common features are designated by common reference numbers throughout the drawings.

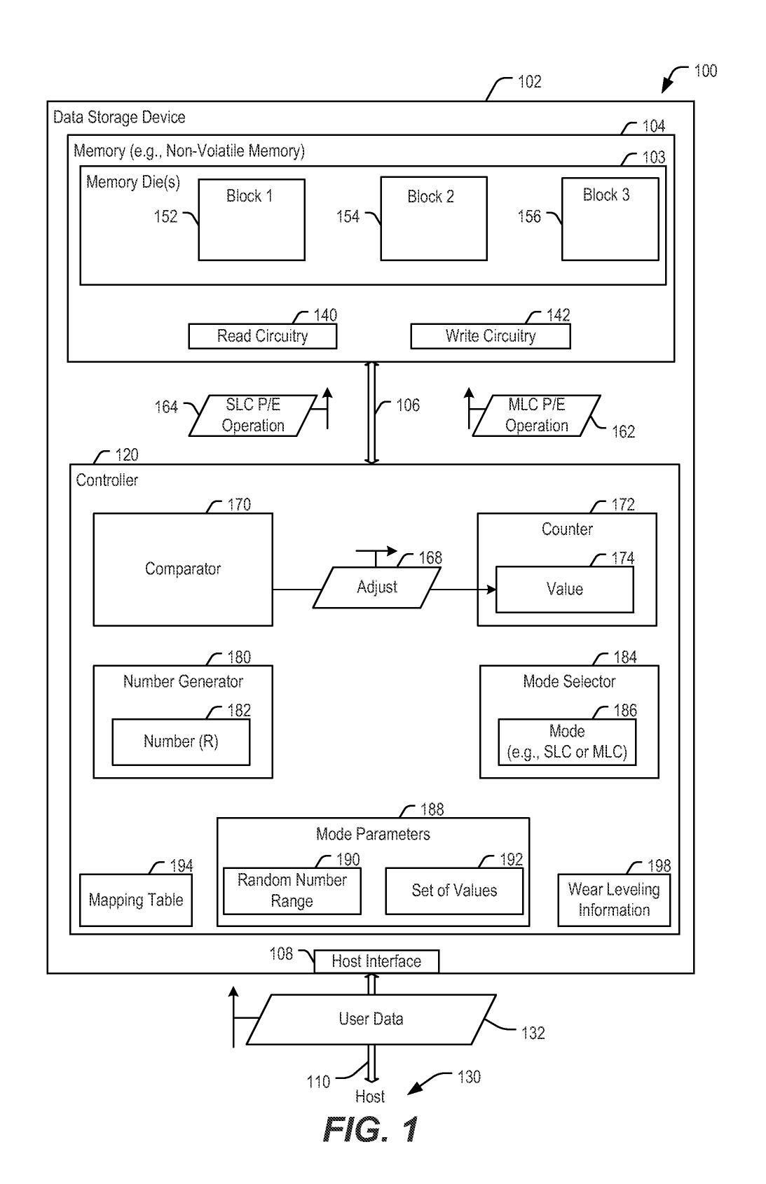

FIG. 1 is a block diagram of a particular illustrative embodiment of a system 100 including a data storage device 102 and a host device 130. The data storage device 102 includes a controller 120 (e.g., a memory controller) coupled to a memory 104 including one or more memory dies 103. The one or more memory dies 103 may include multiple blocks 152-156. The data storage device 102 is configured to track, for each block 152-156, a portion of a total number of program/erase (P/E) cycles associated with the block by selectively adjusting the value of the counter based on generated random numbers. As used herein, randomly generated numbers include random or pseudo-random generated numbers.

To illustrate, the data storage device 102 may detect an operation associated with a block of the memory 104. The operation may be associated with a P/E cycle, such as a write operation or an erase operation. Based on the detected operation, the data storage device 102 may perform a comparison between a random number and at least one value of a set of values. Based on the comparison, the data storage device 102 may selectively adjust (e.g., increment or decrement) a value of a counter associated with the block. For example, the random number may be generated such that the random number is constrained within a range and the random number may be compared to a particular value of the set of values. When the random number is equal to the particular value, the value of the counter may be adjusted (e.g., incremented or decremented). The value of the counter may be associated with a total number of P/E cycles associated with the block.

The data storage device 102 may be embedded within the host device 130, such as in accordance with an embedded MultiMedia Card (eMMC®) (trademark of Joint Electron Devices Engineering Council (JEDEC) Solid State Technology Association, Arlington, Va.) configuration. Alternatively, the data storage device 102 may be removable from (i.e., “removably” coupled to) the host device 130. For example, the data storage device 102 may be removably coupled to the host device 130 in accordance with a removable universal serial bus (USB) configuration. In some implementations, the data storage device 102 may include or correspond to a solid state drive (SSD), which may be used as an embedded storage drive, an enterprise storage drive (ESD), or a cloud storage drive (CSD), as illustrative, non-limiting examples.

The data storage device 102 may be configured to be coupled to the host device 130 via a communication path 110, such as a wired communication path and/or a wireless communication path. For example, the data storage device 102 may include an interface 108 (e.g., a host interface) that enables communication (via the communication path 110) between the data storage device 102 and the host device 130, such as when the interface 108 is coupled to the host device 130.

For example, the data storage device 102 may be configured to be coupled to the host device 130 as embedded memory, such as eMMC® (trademark of JEDEC Solid State Technology Association, Arlington, Va.) and eSD, as illustrative examples. To illustrate, the data storage device 102 may correspond to an eMMC (embedded MultiMedia Card) device. As another example, the data storage device 102 may correspond to a memory card, such as a Secure Digital (SD®) card, a microSD® card, a miniSD™ card (trademarks of SD-3C LLC, Wilmington, Del.), a MultiMediaCard™ (MMC™) card (trademark of JEDEC Solid State Technology Association, Arlington, Va.), or a CompactFlash® (CF) card (trademark of SanDisk Corporation, Milpitas, Calif.). The data storage device 102 may operate in compliance with a JEDEC industry specification. For example, the data storage device 102 may operate in compliance with a JEDEC eMMC specification, a JEDEC Universal Flash Storage (UFS) specification, one or more other specifications, or a combination thereof.

The host device 130 may include a processor and a memory. The memory may be configured to store data and/or instructions that may be executable by the processor. The memory may be a single memory or may include one or more memories, such as one or more non-volatile memories, one or more volatile memories, or a combination thereof. The host device 130 may issue one or more commands to the data storage device 102, such as one or more requests to erase, read data from, or write data to the memory 104 of the data storage device 102. For example, the host device 130 may be configured to provide data, such as user data 132, to be stored at the memory 104 or to request data to be read from the memory 104. The host device 130 may include a mobile telephone, a music player, a video player, a gaming console, an electronic book reader, a personal digital assistant (PDA), a computer, such as a laptop computer or notebook computer, any other electronic device, or any combination thereof. The host device 130 communicates via a memory interface that enables reading from the memory 104 and writing to the memory 104. For example, the host device 130 may operate in compliance with a Joint Electron Devices Engineering Council (JEDEC) industry specification, such as a Universal Flash Storage (UFS) Host Controller Interface specification. As other examples, the host device 130 may operate in compliance with one or more other specifications, such as a Secure Digital (SD) Host Controller specification, as an illustrative, non-limiting example. The host device 130 may communicate with the memory 104 in accordance with any other suitable communication protocol.

The data storage device 102 includes the controller 120 coupled to the memory 104 that includes the one or more memory dies 103. The controller 120 may be coupled to the one or more memory dies 103 via a bus 106, an interface (e.g., interface circuitry), another structure, or a combination thereof. For example, the bus 106 may include multiple distinct channels to enable the controller 120 to communicate with each of the one or more memory dies 103 in parallel with, and independently of, communication with the other memory dies 103. In some implementations, the memory 104 may be a flash memory.

Each of the one or more memory dies 103 may include one or more blocks (e.g., one or more memory blocks). For example, a particular memory die of the one or more memory dies 103 may include the blocks 152-156. A particular block may include multiple word lines, and each word line may include (e.g., may be coupled to) multiple storage elements (e.g., multiple memory cells). For example, each storage element may be configured as a single-level cell (SLC, storing one bit per storage element) or a multi-level cell (MLC, storing multiple bits per storage element). Alternatively or additionally, one or more of the blocks 152-156 may be a hybrid block where the storage elements of the block may be able to operate according to multiple modes, such as a first mode where each storage element is configured to store one bit per storage element, a second mode where each storage element is configured to store two bits per storage element, and/or a third mode where each storage element is configured to store three bits person storage element, as an illustrative, non-limiting example. In some implementations, each block is an erase unit and data is erasable from the memory 104 according to a block-by-block granularity. The one or more of the memory dies 103 may include a two dimensional (2D) memory configuration, a three dimensional (3D) memory configuration, or a combination thereof. The memory 104 may store data, such as the user data 132 or encoded user data, such as a codeword.

The memory 104 may include support circuitry associated with the memory 104. For example, the memory 104 may be associated with circuitry to support operation of the storage elements of the blocks 152-156, such as read circuitry 140 and write circuitry 142. Although depicted as separate components, the read circuitry 140 and the write circuitry 142 may be combined into a single component (e.g., hardware and/or software) of the memory 104. Although the read circuitry 140 and the write circuitry 142 are depicted as external to the one or more memory dies 103, each individual memory die may include read and write circuitry that is operable to read and/or write from the individual memory die independent of any other read and/or write operations at any of the other memory dies 103.

The controller 120 is configured to receive data and instructions from and to send data to the host device 130 while the data storage device 102 is operatively coupled to the host device 130. The controller 120 is further configured to send data and commands to the memory 104 and to receive data from the memory 104. For example, the controller 120 is configured to send data and a write command to instruct the memory 104 to store the data to a specified block. For example, the controller 120 may be configured to send a first portion of write data and a first physical address (e.g., corresponding to the block 152). The controller 120 may be configured to send a read request to the memory 104 to read the first portion from the first physical address. The controller 120 may also be configured to send an erase request to the memory 104 to erase a portion of the memory 104, such as one or more of the blocks 152-156. The controller 120 may send the erase request responsive to data and/or instructions received from the host device 130, or the controller 120 may generate and initiate the erase request without input from the host device 130.

The controller 120 may be configured to send a SLC P/E operation 164 and/or a MLC P/E operation 162 to one or more of the blocks 152-156. When a particular block is configured as a SLC block, the controller 120 may send the SLC P/E operation 164, such as a SLC write operation or a SLC erase operation, to the particular block. When the particular block is configured as a MLC block, the controller may send the MLC P/E operation 162, such as a MLC write operation or a MLC erase operation, to the particular block.

The controller 120 may include a comparator 170, a counter 172, a number generator 180 (e.g., a random number generator, such as a pseudo-random number generator), and a mode selector 184. The controller 120 may be configured to store mode parameters 188, a mapping table 194, and wear leveling information 198. The counter 172 may be configured to store a value 174, and the number generator 180 may be configured to generate a number (R) 182, such as a random number.

The counter 172 may be associated with a particular block of the memory 104, such as the block 152. For example, the counter 172 may be associated with a number of P/E cycles corresponding to the block 152. In a particular implementation, the counter 172 may be an 8-bit counter. Although, the data storage device 102 is illustrated as having a single counter, the data storage device 102 may include multiple counters. For example, each block of the memory 104 may be associated with a corresponding counter.

During operation of the data storage device 102, the counter value 174 may be initialized to an initial value. In some implementations, the initial value may be a value of zero and the counter value (corresponding to a block) may be incremented based on one or more P/E cycles associated with the block. In other implementations, the initial value may be a value associated with an endurance (e.g., a life of) the block that corresponds to the counter and the counter value may be decremented based on one or more P/E cycles associated with the block.

The mode selector 184 may be configured to select a mode 186 (e.g., a mode of operation) for each of the blocks 152-156. For example, the mode selector 184 may select the block 152 to operate in a single-level cell (SLC) mode or in a multi-level cell (MLC) mode. Although the mode selector 184 is described as setting the mode 186 as one of two different modes, in other implementations the mode selector 184 may be able to choose from three or more modes. For example, a first mode may be associated with the block storing one bit per cell, a second mode may be associated with the block storing two bits per cell, and a third mode may be associated with the block storing three bits per cell. The mapping table 194 may be configured to track what mode each block of the memory 104 is operating in, such as the SLC mode or the MLC mode.

The mode parameters 188 may include or correspond to one or more number ranges 190 and/or one or more sets of values 192. Each of the one or more number ranges 190 may be associated with a range of values that may be used to constrain generation of the number (R) 182 by the number generator 180, as described further herein. In a particular implementation, a first random number range of the one or more number ranges 190 (e.g., one or more random number ranges) may correspond to the SLC mode and a second random number range of the one or more number ranges 190 may correspond to the MLC mode. Each set of values of the one or more sets of values 192 may be used in a comparison between the number (R) 182 and the set of values, as described further herein. In another particular implementation, a first set of values of the one or more sets of values 192 may correspond to the SLC mode and a second set of values of the one or more sets of values 192 may correspond to the MLC mode. Each set of values included in the sets of values 192 may include one or more values.

As an illustrative example of the mode parameters 188, a first number range of the one or more number ranges 190 and a first set of values of the one or more sets of values 192 may correspond to a 1 bit per cell mode, a second number range of the one or more number ranges 190 and a second set of values of the one or more sets of values 192 may correspond to a two bit per cell mode, and a third number range of the one or more number ranges 190 and a third set of values of the one or more sets of values 192 may correspond to a 3 bit per cell mode, as illustrative, non-limiting examples. In some implementations, each of the first number range, the second number range, and the third number range may be different number ranges. In other implementations, one or more of the first number range, the second number range, and the third number range may be the same range. Additionally or alternatively, each of the first set of values, the second set of values, and the third set of values may be different sets of values. In other implementations, one or more of the first set of values, the second set of values, and the third set of values may be the same set of values.

The number generator 180 may be configured to generate numbers, such as binary numbers representing integer values, that are random or pseudo-random. The number generator 180 may generate a number (R) 182 such that the number (R) 182 is constrained within a range, such as a range selected from the one or more number ranges 190. The number generator 180 may generate a new number (R) based on an operation, such as the SLC P/E operation 164 or the MLC P/E operation 162. For example, the number generator 180 may generate a new number in response to receiving a write command (e.g., associated with a SLC write operation or a MLC write operation), in response to a write operation being started (e.g., the SLC write operation or the MLC write operation), in response to the write operation be completed, in response to receiving an erase command (e.g., associated with a SLC erase operation or a MLC erase operation), in response to an erase operation being started (e.g., the SLC erase operation or the MLC erase operation), and/or in response to the erase operation be completed, as illustrative, non-limiting examples.

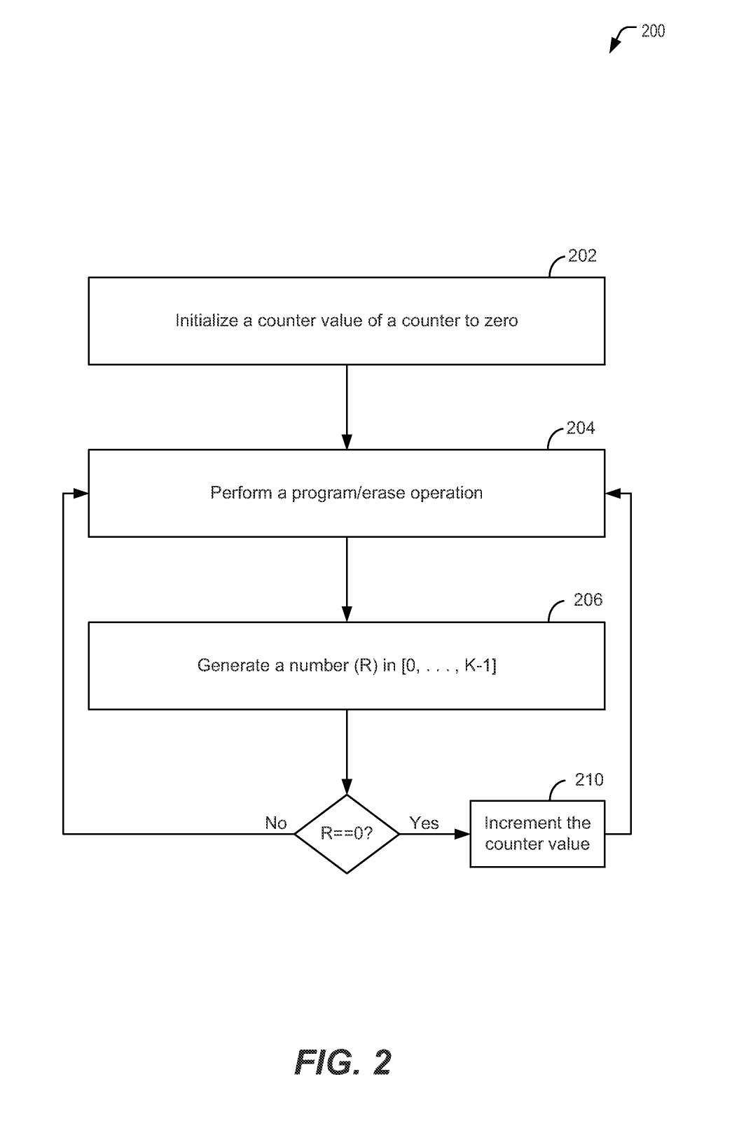

The comparator 170 may be configured to compare the number (R) 182 to one or more values, as described further herein with reference to FIGS. 2-6. The one or more values compared to a particular number (R) by the comparator 170 may be constrained by the same range that is used to generate the particular number (R) 182 (e.g. the one or more values may be included within the range used to generate the particular number (R) 182).

As an example of the operation of the comparator 170, the comparator 170 may be configured to compare the number (R) 182 to a predetermined value (e.g., a zero value). In some implementations, the comparator 170 may determine whether the number (R) 182 matches the predetermined value. In other implementations, the predetermined value may be a threshold value and the comparator 170 may determine whether the number (R) 182 satisfies the threshold value. For example, the comparator 170 may determine that the number (R) 182 satisfies the threshold value in response to determining that the number (R) 182 is greater than or equal to the threshold value. As another example, the comparator 170 may determine that the number (R) 182 satisfies the threshold value in response to determining that the number (R) 182 is less than or equal to the threshold value.

As another example, the comparator 170 may be configured to compare the number (R) 182 to a particular set of values selected from the one or more sets of values 192. The particular set of values may include one or more values. When the particular set of values includes a single value, the comparator 170 may perform a comparison between the number (R) 182 and the single value, as though the single value were the predetermined value as described above. When the particular set of values includes multiple values, the comparator 170 may compare the number (R) 182 to one or more values of the particular set of values to determine whether the number (R) 182 matches a value in the set. In some implementations, when the particular set of values includes two values, the values may be associated with a threshold range. For example, a first value of the two values may correspond to a minimum value of the threshold range and a second value may correspond to a maximum value of the threshold range. When the particular set of values is associated with the threshold range, the comparator 170 may determine whether the number (R) 182 satisfies the threshold range. For example, the comparator 170 may determine that the number (R) 182 satisfies the threshold range in response to determining that the number (R) 182 has a value that is included within the threshold range. As another example, the comparator 170 may determine that the number (R) 182 satisfies the threshold value in response to determining that the number (R) 182 has a value that is not included within the threshold range.

Based on the comparison, the comparator 170 may send an adjust signal 168 to the counter 172 to cause the value 174 of the counter to be adjusted (e.g., incremented or decremented). For example, the comparator 170 may send the adjust signal 168 when the number (R) 182 matches a particular value. As another example, the comparator 170 may send the adjust signal 168 when the number (R) 182 satisfies a threshold value (or a threshold range).

A total number of P/E cycles experienced by a particular block may be associated with an endurance of the particular block, such as a total number P/E cycles that is estimated to be able to be performed at storage elements of the block without impairing reliability of the particular block. The total number of P/E cycles that can be performed at the particular block may depend on a mode of the particular block.

A particular number range of the one or more number ranges 190 and/or a particular set of values of the sets of values 192 may be determined and/or selected to statistically adjust the value 174 of the counter 172 such that the counter 172 may track less than a total number of P/E cycles of a particular block that correspond to the counter 172, as described further with reference to FIGS. 2-6. As an illustrative, non-limiting example, an endurance of a particular block in a particular mode may be 512 P/E cycles, the particular number range may include values of 0 through 255, and the particular set of values may include values 0-127. Accordingly, when in the particular block is in the particular mode, the number (R) 182 may be generated to be a value (e.g., an integer value) that is constrained by the particular range of 0 through 255 and the comparator 170 may compare the number (R) 182 to the set of values that include values 0-127. Accordingly, when in the particular mode, the counter 172 may be adjusted 50% of the time the particular block experiences a P/E cycle. Thus the value 174 may be a number that reflect approximately half of the total number of P/E cycles and the counter 172 may be sized to be half the size as a counter configured to count the total number of P/E cycles. To illustrate, if two 8-bit counters would be needed to track a total of 512 P/E cycles, a single 8-bit counter may be used when the value 174 reflects approximately half of the total number of P/E cycles.

Additionally, when the particular block operates in a 1 bit per cell mode, the total number of P/E cycles that can be performed at the particular block may be several hundred thousand or more P/E cycles. When the particular block operates in a two bits per cell mode, the total number of P/E cycles that can be performed at the particular block may be less than the total number of P/E cycles that can be performed when the particular block operates in the one bit per cell mode. When the particular block operates in a three bits per cell mode, the total number of P/E cycles that can be performed at the particular block may be less than the total number of P/E cycles that can be performed when the particular block operates in the two bits per cell mode. When the particular block can be operated in different modes at different time, such as in the 2 bits per cell mode during a first time period and in the 3 bits per cell mode during a second time period, the total number of P/E cycles that can be performed at the particular block may depend on a number of P/E cycles the block experiences in each mode (e.g., during each time period).

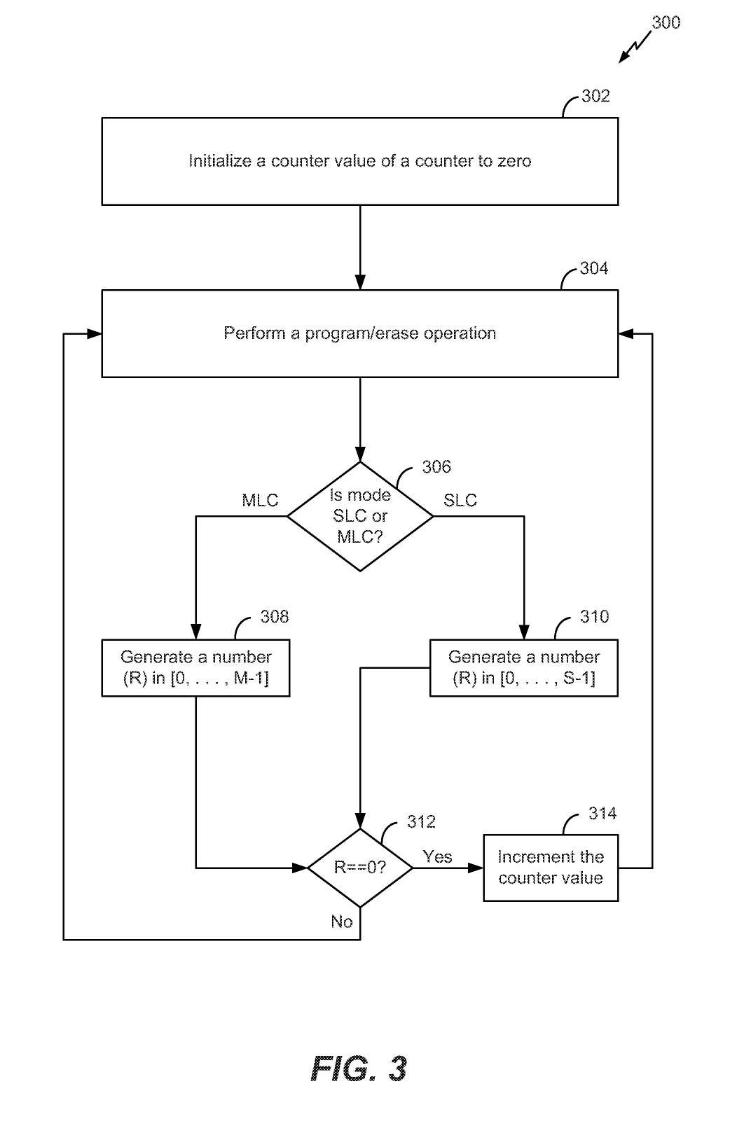

A particular number range of the one or more number ranges 190 and/or a particular set of values of the one or more sets of values 192 may be determined and/or selected based on the mode 186 to statistically adjust the value 174 of the counter 172 at different rates, as described further with reference to FIGS. 3, 5, and 6. For example, when a particular block is in a first mode, such as a 1 bit per cell mode, a first number range and/or a first set of values may be selected such that the value 174 of the counter 172 corresponding to the particular block is statistically adjusted at a first rate and, when the particular block is in a second mode, such as the 2 bits per cell mode, a second number range and/or a second set of values may be selected such that the value 174 of the counter is statistically adjusted at a second rate. The second rate may result in the value 174 being adjusted more often (i.e., at a higher rate) than the first rate.

When the particular block is able to be operated in the first mode during a first time period and operated in the second mode during a second time period, the first rate and the second rate may be selected to normalize a number of P/E cycles experienced by the particular block in the first mode and a number of P/E cycles experienced by the particular block in the second mode. To illustrate, if an endurance of the particular block in the second mode is half of the endurance of the block in the first mode, the second rate may be selected to increment the value 174 of the counter 172 twice as often as the first rate. By using different rates to normalize the total number of P/E cycles experienced the particular block, a single counter may be used to track the number of P/E cycles experience by the particular block.

The controller 120 may access the mapping table 144 to identify the counter 172 associated with a particular block, such as the block 152. For example, the mapping table 144 may identify multiple blocks (e.g., physical addresses of the blocks of the memory 104) and counters associated with the multiple blocks. In an illustrative example, the user data 132 is to be written the block 152, and the controller 120 is configured to access the mapping table 144 to determine that the counter 172 is associated with one or more physical addresses associated with the block 152.

The controller 120 may be configured to use the value 174 in connection with wear leveling operations at the memory 104. To illustrate, the value 174 of the counter 172 may be associated with a particular block of the memory 104, that stores the user data 132. In this example, the value 174 indicates an approximate number of P/E cycles associated with the block of the memory 104 that stores the user data 132. The controller 120 may be configured to determine whether the value 174 satisfies a P/E threshold. If the value 174 satisfies the P/E threshold, the controller 120 may initiate a wear leveling process at the memory 104. For example, the controller 120 may access the wear leveling information 198 to determine another block of the memory 104 at which to relocate the user data 132, such as a block that has a corresponding counter value that does not satisfy the P/E threshold. In this example, the controller 120 may cause the user data 132 to be moved from the block because the block is approaching an end-of-life condition (e.g., the block is becoming less reliable). In certain implementations, the controller 120 may update the wear leveling information 198 to indicate that the block should be used less frequently to store data. In other implementations, the controller 120 may update the wear leveling information 198 to indicate that the block should not be used for additional write operations (e.g., to “close” the block to further write operations in response to a large number of P/E cycles at the block).

During operation, the controller 120 may detect an operation to be performed at a block, such as a P/E operation to be performed at the block 152. Responsive to the operation, the controller 120 may determine the mode 186 of the block 152. For example, the controller 120 may determine whether the mode 186 is the SLC mode or the MLC mode. Based on the mode 186, controller 120 may send the SLC P/E operation 164 or the MLC P/E operation 162 to the memory 104 to be performed on the block 152.

The controller 120 may identify a particular number range of the one or more number ranges 190 and/or a particular set of values of the one or more sets of values 192 based on the mode 186. The number generator 180 may generate the number (R) 182 to be constrained within the particular number range. The comparator 170 may compare the number (R) 182 to the particular set of values (e.g., one or more values) to determine whether the value 174 of the counter 172 (corresponding to the block 152) is to be adjusted (e.g., incremented or decremented). When the comparator 170 determines to adjust the value 174, the comparator may send the adjust signal 168 to the counter 172 and the counter 172 may adjust the value 174 responsive to the adjust signal 168.

In some implementations, the controller 120 may include one or more memories, such as a random access memory. The one or more memories may be configured to store the value 174, the mode parameters 188, the mapping table 194, and/or the wear leveling information 198. In other implementations, at least a portion of the value 174, the mode parameters 188, the mapping table 194, and/or the wear leveling information 198 may be stored at the memory 104, at a memory of the host device 130, at another memory that is coupled to the controller 120, or a combination thereof.

Although the comparator 170, the counter 172, the number generator 180, and the mode selector 184 are illustrated as being included in the controller 120, the comparator 170, the counter 172, the number generator 180, the mode selector 184, and/or functions thereof may be located at locations other than in the controller 120 or performed by a component other than the controller 120. For example, the comparator 170, the counter 172, the number generator 180, and the mode selector 184 may be included in the memory 104, such as being included in one of the memory dies 103, or in the host device 130. As another example, functionality described with respect to the comparator 170, the counter 172, the number generator 180, and the mode selector 184 may be performed by one or more components of memory, such as by one or more of the memory die 103, and/or one or more components of the host device 130.

The example of FIG. 1 illustrates that the value 174 can be selectively updated to statistically indicate a number of program/erase (P/E) cycles. To illustrate, the value 174 of the counter 172 may be selectively programmed based on the mode 186 of a particular block that corresponds to the counter 172. By selectively incrementing the value 174 of the counter 172 based on the mode 186, the value 174 is statistically expected to approximate a number of P/E cycles at the block that corresponds to the counter 172. The controller 120 may utilize the value 174 in connection with estimating an end-of-life associated with the block and/or in connection with wear leveling operations at the memory 104, which may avoid data corruption associated with storing data at the block associated with a large number of P/E cycles. Additionally, by not counting every P/E cycle, a size of the counter 172 may be reduced as compared to a counter that is configured to be adjusted for every P/E cycle. Additionally, by selecting different sizes of the range and/or different values to be included in the set of one or more values, different rates of counting may be realized. For example, a first rate of counting may be associated with a multi-level cell (MLC) block and a second rate of counting may be associated with a single-level cell (SLC) block. Further, by changing the size of the range and/or the values included in the set of one or more values, a common counter may be used to count a number of P/E cycles for a hybrid block (e.g., a block that can switch between operating as an MLC block and an SLC block).

Referring to FIG. 2, an illustrative embodiment of a method 200 to count program/erase cycles is shown. The method 200 may be performed by the controller 120 or the memory 104 of the data storage device 102, or by the host device 130 of FIG. 1, as illustrative, non-limiting examples.

The method 200 may include initializing a counter value of a counter to zero, at 202. For example, the counter and the counter value may include or correspond to the counter 172 and the counter value 174 of FIG. 1. The counter may correspond to a block of a memory, such as one of the blocks 152-156 of the memory 104 of FIG. 1. For example, the counter may be configured to track a portion of a total number of program/erase cycles associated with the block by selectively adjusting the value of the counter based on randomly generated numbers, as described further herein. Although the counter value is described as being initialized to zero, in other implementations the counter value may be initialized to a number other than zero.

The method 200 may include performing a program/erase operation, at 204. For example, the program/erase operation may include a write operation or an erase operation associated with the block. For example, the program/erase operation may include or correspond to the SLC P/E operation 164 or the MLC P/E operation 162 of FIG. 1.

The method 200 may include generating a random number (R) constrained within a range of 0 through (k−1), where k is a positive integer greater than 1, at 206. The range may include the values of 0 and (k−1). For example, the range may include or correspond to a particular range of the one or more ranges 190 of FIG. 1. The random number (R) may include or correspond to the number (R) 182 that is generated by the number generator 180 of FIG. 1. In some implementations, the random number (R) may be an integer.

The method 200 may include determining whether the random number (R) is equal to a value of zero, at 208. For example, the random number (R) may be compared to the value of zero by the comparator 170 of FIG. 1. The determination may be made prior to, during, or after completion of the program/erase operation.

When a determination is made that the random number (R) is not equal to zero, the method 200 may advance to 204. Alternatively, when a determination is made that the random number (R) is equal to zero, the counter value may be incremented, at 210. After the counter value is incremented at 210, the method 200 may advance to 204. Although the counter value is described as being incremented, in other implementations the counter value may be otherwise adjusted, such as being decremented.

The counter value may have a probability of (1/k) to be adjusted with each program/erase operation. For example, when k=4, the random number (R) may be constrained to the set of [0, 1, 2, 3]. Accordingly, by comparing the random number (R) to the value of zero when k=4, (statistically) the counter value should be adjusted responsive to 25% of the program/erase operations. As another example, when k=8, the random number (R) may be constrained to the set of [0, 1, 2, 3, 4, 5, 6, 7]. Accordingly, by comparing the random number (R) to the value of zero when k=8, (statistically) the counter value should be adjusted responsive to 12.5% of the program/erase operations. Thus, the probability of adjusting the counter value may be based on a range that is used to constrain generation of the random number (R).

The counter value may be representative of a total number of program/erase cycles experience by the block. For example, when the counter value is initialized to zero and incremented, the counter value may be used to determine an approximation of the total number of program/erase cycles based on:

y=x*k+k/2,

where y is the approximation of the total number of program/erase cycles and x is the counter value.

In some implementations, after the counter value is adjusted (e.g., incremented or decremented), the counter value may be compared to an end-of-life threshold associated with the block. When the counter value satisfies the end-of-life threshold value, an indication may be generated that the block is near or approaching an end-of-life condition. In some implementation, such as when the counter is incremented, the counter value may be determined to satisfy the end-of-life threshold when the counter value is greater than or equal to a first end-of-life threshold. In other implementations, such as when the counter is decremented from a non-zero initial value, the counter value may be determined to satisfy the end-of-life threshold when the counter value is less than or equal to a second end-of-life threshold.

Although the random number (R) is described as being constrained within a range of 0 through (k−1), in other implementations the random number (R) may be constrained within another range, such as a range of 1 through k. In implementations where the random number (R) is constrained to a range other than 0 through (k−1), the determination at 208 may determine whether the random number (R) is equal to one or more numbers other than zero, such as one or more numbers that are constrained within the same range that is used to constrain generation of the random number (R).

Although the determination is described as whether the random number (R) is equal to zero, in some implementations the random number (R) may instead be compared to one or more non-zero values. For example, the random number (R) may be compared to a particular value other than zero, such that the particular value is a value that is included within the range that is used to constrain generation of the random number (R), such as the range 0 through (k−1).

In other implementations, rather than comparing the random number (R) to the value of zero, at 208, the random number (R) may be compared to a threshold value or a threshold range. For example, the random number (R) may be compared to a threshold value that constrained within the same range that is used to constrain generation of the random number (R). In such cases, the counter value may be incremented when the random number (R) satisfies the threshold value, such as when the random number (R) is greater than or equal to the threshold value. To illustrate, when k=4 (i.e., the random number (R) is constrained to the set of [0, 1, 2, 3]), the threshold value may be equal to 1 and the counter value may be adjusted when the random number (R) is less than or equal to threshold value of 1.

As another example, the may be compared to a threshold range that is constrained within (e.g., at least partially overlaps) the same range that is used to constrain generation of the random number (R). In such cases, the counter value may be incremented when the random number (R) satisfies the threshold range, such as when the random number (R) matches (e.g., is equal to) a value included in the threshold range. To illustrate, when k=4 (i.e., the random number (R) is constrained to the set of [0, 1, 2, 3]), the threshold range may be range that is greater than or equal to 1 and less than or equal to 3. Accordingly, the counter value may be adjusted when the random number (R) is greater than or equal to 1 and less than or equal to threshold value of 3.

By using the random number (R) to determine when to adjust the counter value, an approximation of a total number of program/erase cycles corresponding to the block may be tracked without having to account for (e.g., track) each and every program/erase cycle corresponding to the block. Accordingly, by approximating the total number of program/erase cycles, a size of a program/erase counter corresponding to the block may be smaller as compared to a counter in a system that maintains an actual number of program/erase cycle associated with the block.

Referring to FIG. 3, an illustrative embodiment of a method 300 to count program/erase cycles is shown. The method 300 may be performed by the controller 120 or the memory 104 of the data storage device 102, or by the host device 130 of FIG. 1, as illustrative, non-limiting examples.

The method 300 may include initializing a counter value of a counter to zero, at 302. For example, the counter and the counter value may include or correspond to the counter 172 and the counter value 174 of FIG. 1. The counter may correspond to a block of a memory, such as one of the blocks 152-156 of the memory 104 of FIG. 1. For example, the counter may be configured to track a portion of a total number of program/erase cycles associated with the block by selectively adjusting the value of the counter based on randomly generated numbers, as described further herein. Although the counter value is described as being initialized to zero, in other implementations the counter value may be initialized to a number other than zero.

The method 300 may include performing a program/erase operation, at 304. For example, the program/erase operation may include a write operation or an erase operation associated with the block. For example, the program/erase operation may include or correspond to the SLC P/E operation 164 or the MLC P/E operation 162 of FIG. 1.

A determination of whether a mode associated with the block is a single-level cell (SLC) mode or a multi-level cell (MLC) mode may be made, at 306. When a determination is made that the mode is the MLC mode, the method 300 may include generating a random number (R) constrained within a range of 0 through (M−1), where M is a positive integer greater than 1, at 308. The range may include the values of 0 and (M−1). For example, the range of 0 through (M−1) may include or correspond to a particular range of the one or more ranges 190 of FIG. 1. The random number (R) may include or correspond to the number (R) 182 that is generated by the number generator 180 of FIG. 1. In some implementations, the random number (R) may be an integer. After generating the random number (R), at 308, the method 300 may advance to 312.

When a determination is made that the mode is the SLC mode, the method 300 may include generating the random number (R) constrained within a range of 0 through (S−1), where S is a positive integer greater than 1, at 310. For example, the range of 0 through (S−1) may include or correspond to a particular range of the one or more ranges 190 of FIG. 1. The range may include the values of 0 and (S−1). A value of S may be a larger value than a value of M. Accordingly, a size of the random number (R) generated at 310 may be larger than a size of the random number (R) generated at 308. After generating the random number (R), at 310, the method 300 may advance to 312.

The method 300 may include may include determining whether the random number (R) is equal to a value of zero, at 312. For example, the random number (R) may be compared to the value of zero by the comparator 170 of FIG. 1. The determination may be made prior to, during, or after completion of the program/erase operation.

When a determination is made that the random number (R) is not equal to zero, the method 300 may advance to 304. Alternatively, when a determination is made that the random number (R) is equal to zero, the counter value may be incremented, at 314. After the counter value is incremented at 314, the method 300 may advance to 304. Although the counter value is described as being incremented, in other implementations the counter value may be otherwise adjusted, such as being decremented.

The counter value may have different probabilities of being adjusted with each program/erase operation depending on whether the mode is the SLC mode or the MLC mode. For example, when M=4, the random number (R) may be constrained to the set of [0, 1, 2, 3] when the mode is the MLC mode. Accordingly, by comparing the random number (R) to the value of zero when the mode is the MLC mode (i.e., when M=4), (statistically) the counter value should be adjusted responsive to 25% of the program/erase operations. Additionally, when S=8, the random number may be constrained to the set of [0, 1, 2, 3, 4, 5, 6, 7] when the mode is the SLC mode. Accordingly, by comparing the random number (R) to the value of zero when the mode is the SLC mode (i.e., when S=8), (statistically) the counter value should be adjusted responsive to 12.5% of the program/erase operations. Thus, the counter value has a higher probability of being adjusted when the mode is the MLC mode as compared to when the mode is the SLC mode based on the different ranges used to constrain generation of the random number when the mode is the SLC or the MLC mode.

Although the random number (R) is described as being constrained within a range of 0 through (M−1) at 308 or being constrained within a range of 0 through (S−1) at 310, in other implementations, the random number (R) may be constrained within another range, such as a range of 1 through M when the mode is the MLC mode or a range of 1 through S when the mode is the SLC mode.

Although the determination is described as whether the random number (R) is equal to zero, in some implementations the random number (R) may instead be compared to one or more non-zero values. For example, the random number (R) may be compared to a particular value other than zero, such that the particular value is a value that is included within the range that is used to constrain generation of the random number (R) when the block is in the SLC mode and that is included within the range that is used to constrain generation of the random number (R) when the block in the MLC mode.

In other implementations, rather than comparing the random number (R) to the value of 0, at 312, the random number (R) may be compared to a threshold value or a threshold range. For example, the random number (R) may be compared to a threshold value that is included within the range used to constrain the random number R when the block in in the SLC mode (e.g., the range 0 through (S−1)) and included within the range used to constrain the random number (R) when the block is in the MLC mode (e.g., the range 0 through (M−1)). In such cases, the counter value may be incremented when the random number (R) satisfies the threshold value, such as when the random number (R) is greater than or equal to the threshold value. As another example, the random number (R) may be compared to a threshold range that is constrained within (e.g., at least partially overlaps) the same range that is used to constrain generation of the random number (R). In such cases, the counter value may be incremented when the random number (R) satisfies the threshold range, such as when the random number (R) matches (e.g., is equal to) a value included in the threshold range.

Although the method 300 is illustrated as determining whether the block is operating in one of two modes, in other implementations the method 300 may determine whether the block is operating in one of three or more modes. When the block is operating in one of the three modes, the random number (R) may be generated to be constrained within a range that corresponds to the mode the block is operating in.

Thus, the method 300 may use a counter to track a number of program/erase cycles corresponding to the block when the block is in the SLC mode or the MLC mode. The number of program/erase cycles may be tracked using statistical techniques where a probability of adjusting the counter value based on a program/erase operation when the block is in the SLC mode is a different probability than a probability of adjusting the counter value based on a program/erase operation when the block is in the MLC mode. By using different probabilities for the different modes, a single counter may be used to track the program/erase cycles associated with the block regardless of the mode of the block. Additionally, the single counter may be used when the block is able to switch between (e.g., back-and-forth) the SLC mode and the MLC mode. Accordingly, by using a single counter to track a number of program/erase cycles corresponding to the block regardless of the mode of the block, the method 300 may use fewer counters than a system and/or a method that uses multiple counters to track a number of program/erase cycles for each mode of the block (e.g., a first counter to track program/erase cycles corresponding to a particular block in the SLC mode and a second counter to track program/erase cycles corresponding to the particular block in the MLC mode).

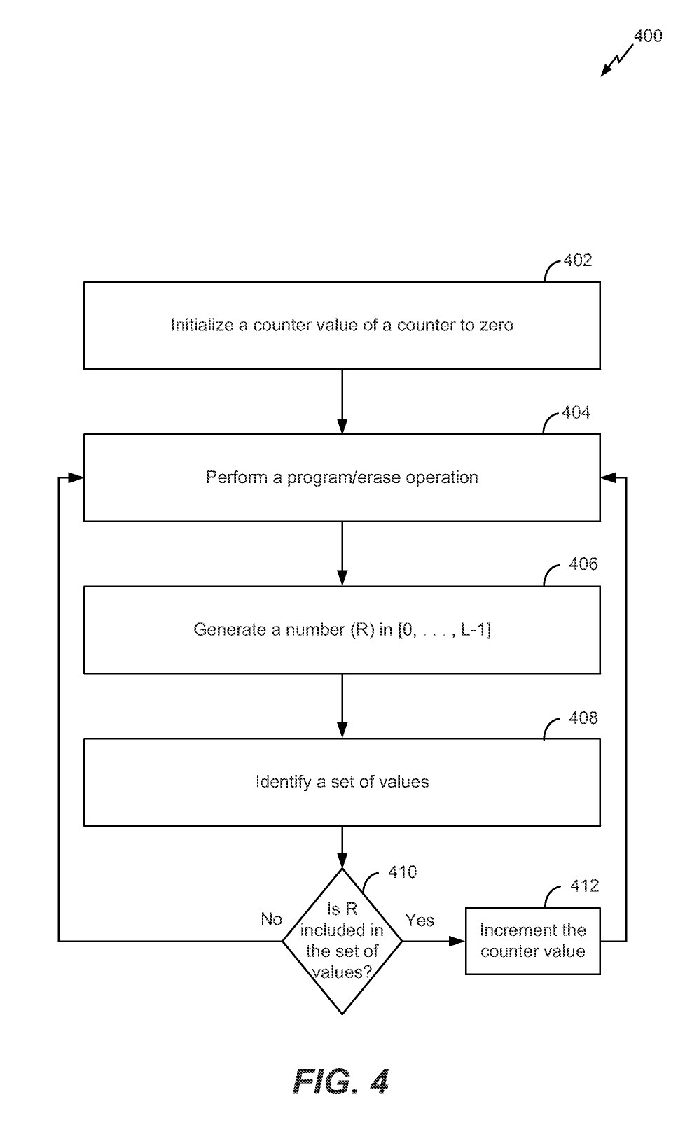

Referring to FIG. 4, an illustrative embodiment of a method 400 to count program/erase cycles is shown. The method 400 may be performed by the controller 120 or the memory 104 of the data storage device 102, or by the host device 130 of FIG. 1, as illustrative, non-limiting examples.

The method 400 may include initializing a counter value of a counter to zero, at 402. For example, the counter and the counter value may include or correspond to the counter 172 and the counter value 174 of FIG. 1. The counter may correspond to a block of a memory, such as one of the blocks 152-156 of the memory 104 of FIG. 1. For example, the counter may be configured to track a portion of a total number of program/erase cycles associated with the block by selectively adjusting the value of the counter based on randomly generated numbers, as described further herein. Although the counter value is described as being initialized to zero, in other implementations the counter value may be initialized to a number other than zero.

The method 400 may include performing a program/erase operation, at 404. For example, the program/erase operation may include a write operation or an erase operation associated with the block. For example, the program/erase operation may include or correspond to the SLC P/E operation 164 or the MLC P/E operation 162 of FIG. 1.

The method 400 may include generating a random number (R) constrained within a range of 0 through (L−1), where L is a positive integer greater than 1, at 406. The range may include the values of 0 and (L−1). For example, the random number (R) may include or correspond to the number (R) 182 that is generated by the number generator 180 of FIG. 1. In some implementations, the random number (R) may be an integer. Although the random number (R) is described as being constrained within a range of 0 through (L−1), in other implementations, the random number (R) may be constrained within another range, such as a range of 1 through L.

The method 400 may include identifying a set of values, at 408. For example, the set of values may include or correspond to a particular set of values of the one or more sets of values 192 of FIG. 1. Each value included in the set of values may be constrained by the same range used to constrain generation of the random number (R), such as the range of 0 through (L−1).

The method 400 may include determining whether the random number (R) is included in the set of values, at 410. For example, the random number (R) may be compared to one or more value of set of values to determine whether the random number (R) matches a particular value of the set of values. The determination whether random number (R) is included in the set of values may be made by the comparator 170 of FIG. 1. The determination may be made during or after the program/erase operation.

When a determination is made that the random number (R) is not included in the set of values, the method 400 may advance to 404. Alternatively, when a determination is made that the random number (R) is included in the set of values (e.g., matches a particular value of the set of values), the counter value may be incremented, at 412. After adjusting the counter value at 412, the method 400 may advance to 404. Although the counter value is described as being incremented, in other implementations the counter may be otherwise adjusted, such as being decremented.

The counter value may have a probability to be adjusted with each program/erase operation based on the set of values. For example, when L=10, the random number (R) may be constrained to the set of [0, 1, 2, 3, 4, 5, 6, 7, 8, 9]. In some implementations, the set of values may include 4 values, such as the values 0, 1, 2, 9. When the random number (R) is compared to the set of values including the 4 values, (statistically) the counter value should be adjusted responsive to 40% of the program/erase operations. In other implementations, the set of values may include 2 values, such as the values 0 and 1 and, when the random number (R) is compared to the set of values including the 2 values, (statistically) the counter value should be adjusted responsive to 20% of the program/erase operations. Thus, the probability of adjusting the counter value may be based on the set of values that the random number (R) is compared to.

The counter value may be representative of a total number of program/erase cycles experience by the block. For example, when the counter value is initialized to zero and incremented, the counter value may be used to determine an approximation of the total number of program/erase cycles based on:

y=x*L+L/2,

where y is the approximation of the total number of program/erase cycles and x is the counter value.

In some implementations, after the counter value is adjusted (e.g., incremented or decremented), the counter value may be compared to an end-of-life threshold associated with the block in a manner similar to the manner described with respect to FIG. 2.

Although the determination, at 410, is described as whether the random number (R) matches at least one value of the set of values, in other implementations a determination may be made whether the random number (R) does not match any value included in the set of values and the counter value may be adjusted (e.g., incremented or decremented) when the random number (R) does not match any value.

In some implementations, the set of values may include multiple values (e.g., two or more values), such as two or more values that are constrained by the same range used to constrain generation of the random number (R) (e.g., the range of 0 through (L-1)). For example, when the set of values includes two or more values, the two value may define a threshold range (e.g., a first value of the two values may be associated with a minimum value of the first threshold range and a second value of the two values may be associated with a maximum value of the first threshold range). When the set of values define the threshold range, the counter value may be incremented when the random number (R) satisfies the threshold range, such as when the random number (R) matches a value within threshold range.

In other implementations, the set of values may include less than two values (i.e., a single value), and the single value is constrained by the same range used to constrain generation of the random number (R) (e.g., the range of 0 through (L−1)). In some implementations, the single value may be a threshold value. When the single value is the threshold value, the counter value may be incremented when the random number (R) satisfies the threshold value, such as when the random number (R) is less than or equal to the threshold value.

By using the random number (R) to determine when to adjust the counter value, an approximation of a total number of program/erase cycles corresponding to the block may be tracked without having to account for (e.g., track) each and every program/erase cycle corresponding to the block. Accordingly, by approximating the total number of program/erase cycles, a size of a program/erase counter corresponding to the block may be smaller as compared to a counter in a system that maintains an actual number of program/erase cycle associated with the block.

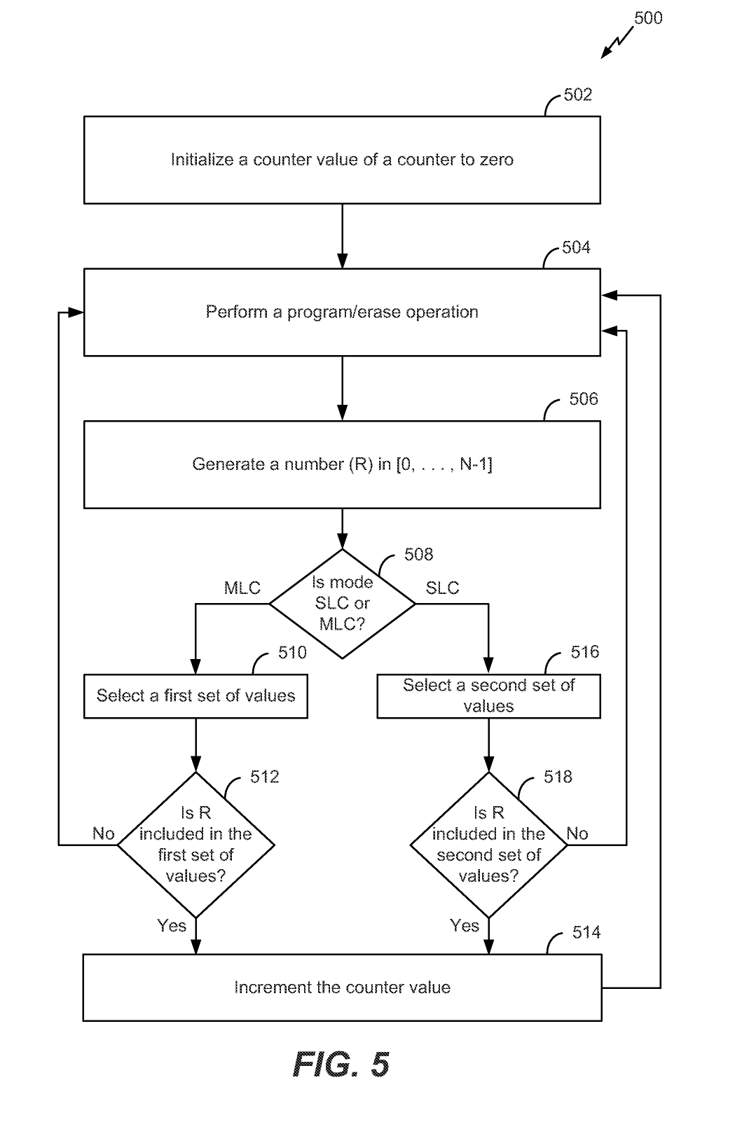

Referring to FIG. 5, an illustrative embodiment of a method 500 to count program/erase cycles is shown. The method 500 may be performed by the controller 120 or the memory 104 of the data storage device 102, or by the host device 130 of FIG. 1, as illustrative, non-limiting examples.

The method 500 may include initializing a counter value of a counter to zero, at 502. For example, the counter and the counter value may include or correspond to the counter 172 and the counter value 174 of FIG. 1. The counter may correspond to a block of a memory, such as one of the blocks 152-156 of the memory 104 of FIG. 1. For example, the counter may be configured to track a portion of a total number of program/erase cycles associated with the block by selectively adjusting the value of the counter based on randomly generated numbers, as described further herein. Although the counter value is described as being initialized to zero, in other implementations the counter value may be initialized to a number other than zero.

The method 500 may include performing a program/erase operation, at 504. The program/erase operation may include a write operation or an erase operation associated with the block. For example, the program/erase operation may include or correspond to the SLC P/E operation 164 or the MLC P/E operation 162 of FIG. 1.

The method 500 may include generating a random number (R) constrained within a range of 0 through (N−1), where N is a positive integer greater than 1, at 506. The range may include the values of 0 and (N−1). For example, the random number (R) may include or correspond to the number (R) 182 that is generated by the number generator 180 of FIG. 1. In some implementations, the random number (R) may be an integer. Although the random number (R) is described as being constrained within a range of 0 through (N−1), in other implementations, the random number (R) may be constrained within another range, such as a range of 1 through N.

The method 500 may include determining whether a mode associated with the block is a single-level cell (SLC) mode or a multi-level cell (MLC) mode, at 508. When a determination is made that the mode is the MLC mode, the method 500 may include selecting a first set of values, at 510. For example, the first set of values may include or correspond to a particular set of values of the one or more sets of values 192 of FIG. 1. The first set of values may be selected based on the mode being the MLC mode. Each value included in the first set of values may be constrained within the same range used to constrain the generated random number (R), at 506, such as the range of 0 through (N−1).

The method 500 may include determining whether the random number (R) is included in the first set of values, at 512. For example, the random number (R) may be compared to one or more value of first set of values to determine whether the random number (R) matches a particular value of the first set of values. The determination whether random number (R) is included in the first set of values may be made by the comparator 170 of FIG. 1. The determination may be made during or after the program/erase operation.

When a determination is made that the random number (R) is not included in the first set of values, the method 500 may advance to 504. Alternatively, when a determination is made that the random number (R) is included in the first set of values (e.g., matches a particular value of the first set of values), the method 500 may include incrementing the counter value, at 514. Although the counter value is described as being incremented, in other implementations the counter may be otherwise adjusted, such as being decremented. After adjusting the counter value at 514, the method 500 may advance to 504.

Referring again to 508, when a determination is made that the mode is the SLC mode, the method 500 may include selecting a second set of values, at 516. The second set of values may be different than the first set of values. For example, the second set of values may include or correspond to another particular set of values of the one or more sets of values 192 of FIG. 1. The second set of values may be selected based on the mode being the SLC mode. Each value included in the second set of values may be constrained within the same range used to constrain the generated random number (R), at 506, such as the range of 0 through (N−1).

The method 500 may include determining whether the random number (R) is included in the second set of values, at 518. For example, the random number (R) may be compared to one or more value of second first of values to determine whether the random number (R) matches a particular value of the second set of values. The determination whether random number (R) is included in the second set of values may be made by the comparator 170 of FIG. 1. The determination may be made during or after the program/erase operation.

When a determination is made that the random number (R) is not included in the second set of values, the method 500 may advance to 504. Alternatively, when a determination is made that the random number (R) is included in the second set of values (e.g., matches a particular value of the second set of values), the method 500 may increment the counter value, at 514. Although the counter value is described as being incremented, in other implementations the counter may be otherwise adjusted, such as being decremented. After adjusting the counter value at 514, the method 500 may advance to 504.

The counter value may have different probabilities of being adjusted with each program/erase operation depending on whether the mode is the SLC mode or the MLC mode. For example, when L=4, the random number (R) may be constrained to the set of [0, 1, 2, 3]. In some implementations, the first set of values (corresponding to the MLC mode) may include 2 values, such as the values 1 and 2. When the random number (R) is compared to the first set of values including the 2 values, (statistically) the counter value should be adjusted responsive to 50% of the program/erase operations. The second set of values may include 1 value, such as a value of 1 and, when the random number (R) is compared to the second set of values including the 1 value, (statistically) the counter value should be adjusted responsive to 25% of the program/erase operations. Thus, the counter value has a higher probability of being adjusted when the mode is the MLC mode as compared to when the mode is the SLC mode based on the different sets of values that correspond to the SLC mode and to the MLC mode.

Although the method 500 is illustrated as determining whether the block is operating in one of two modes, in other implementations the method 500 may include determining whether the block is operating in one of three or more modes. When the block is operating in one of three or more modes, a particular set of values may be selected based on the mode the block is operating in.

In some implementations, the first set of values may include multiple values (i.e., two or more values). For example, when the first set of values includes two values, the two values may define a first threshold range (e.g., a first value of the two values may be associated with a minimum value of the first threshold range and a second value of the two values may be associated with a maximum value of the first threshold range). When the first set of values defines the first threshold range, the counter value may be incremented when the random number (R) satisfies the first threshold range, such as when the random number (R) matches a value within first threshold range. In other implementations, the first set of values may include fewer than two values (i.e., a single value). When the first set of values includes a single value, the single value may be a first threshold (e.g., a first threshold value). When the single value is the first threshold value, the counter value may be incremented when the random number (R) satisfies the first threshold value, such as when the random number (R) is less than or equal to the first threshold value.

Additionally or alternatively, the second set of values may include multiple values (i.e., two or more values) in some implementations and may include fewer than two values (i.e., a single value) in other implementations. For example, when the second set of values includes a single value, the single value may be a second threshold value. When the single value is the second threshold value, the counter value may be incremented when the random number (R) satisfies the second threshold value, such as when the random number (R) is less than or equal to the second threshold value. As another example, when the second set of values includes two values, the two values may define a second threshold range (e.g., a first value of the two values may be associated with a minimum value of the second threshold range and a second value of the two values may be associated with a maximum value of the second threshold range). When the second set of values defines the first threshold range, the counter value may be incremented when the random number (R) satisfies the second threshold range, such as when the random number (R) matches a value within second threshold range.

Although the determination is described as whether the random number (R) matches at least one value of the first set of values, at 512, in other implementations a determination may be made whether the random number (R) does not match any value included in the first set of values, whether the random number (R) satisfies a first threshold or a first threshold range that is based on the first set of values, or whether the random number (R) does not satisfy the first threshold or the first threshold range that is based on the first set of values. Similarly, in other implementations, the determination described at 518 may be made based on whether the random number (R) does not match any value included in the second set of values, whether the random number (R) satisfies a second threshold or a second threshold range that is based on the second set of values, or whether the random number (R) does not satisfy the second threshold or the second threshold range that is based on the second set of values.

By determining the mode associated with the block, the counter value may be selectively adjusted based on the mode. The number of program/erase cycles may be tracked using statistical techniques where a probability of adjusting the counter value based on a program/erase operation when the block is in the SLC mode is a different probability than a probability of adjusting the counter value based on a program/erase operation when the block is in the MLC mode. By using different probabilities for the different modes, a single counter may be used to track the program/erase cycles associated with the block regardless of the mode of the block. Additionally, the single counter may be used when the block is able to switch between (e.g., back-and-forth) the SLC mode and the MLC mode. Additionally, by using a single counter to track a number of program/erase cycles corresponding to the block regardless of the mode of the block.

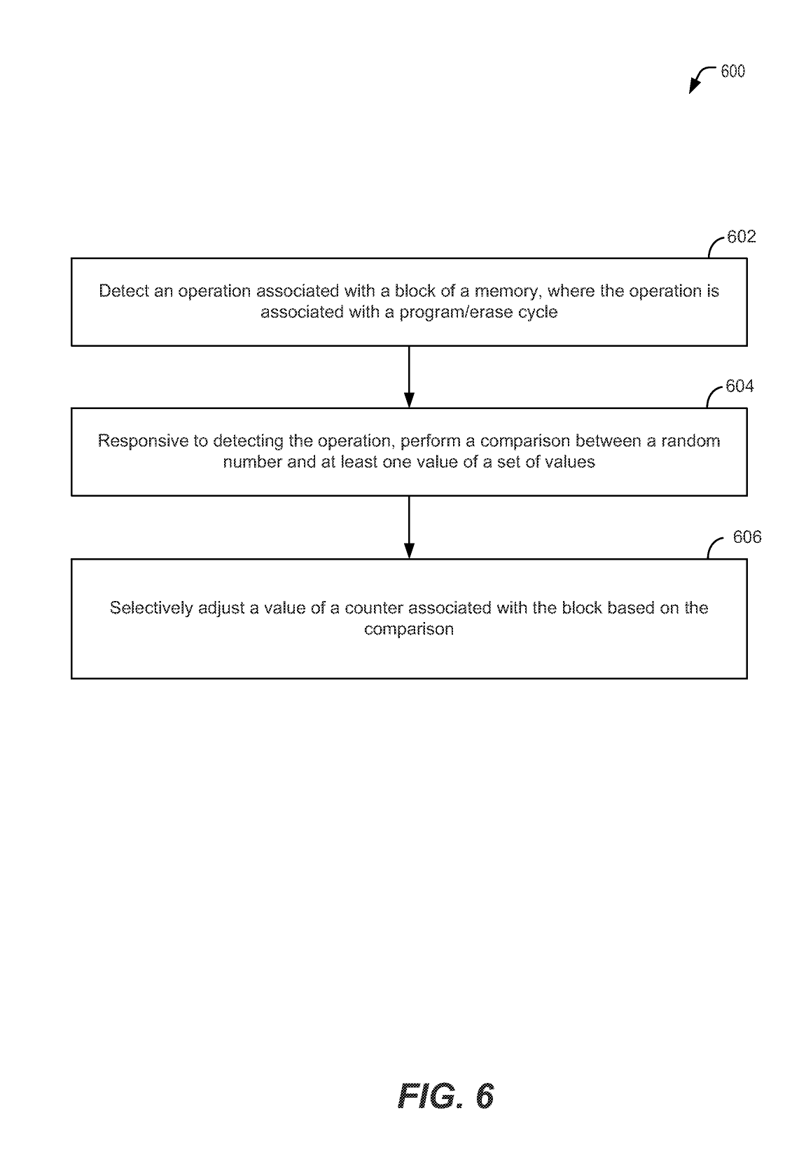

Referring to FIG. 6, another illustrative embodiment of a method 600 to count program/erase cycles is shown. The method 600 may be performed by the controller 120 or the memory 104 of the data storage device 102, or by the host device 130 of FIG. 1, as illustrative, non-limiting examples.

The method 600 includes detecting an operation associated with a block of a memory, where the operation is associated with a program/erase cycle, at 602. The operation may include a write operation or an erase operation. The block may be included in a memory of a data storage device. For example, the data storage device and the memory may include or correspond to the data storage device 102 and the memory 104 of FIG. 1. The block may include one of the blocks 152-156 of FIG. 1. The block may be associated with a corresponding counter (e.g., a program/erase cycle counter). In some implementations, the counter may be configured to track a portion of a total number of program/erase cycles by selectively adjusting the value of the counter based on randomly generated numbers.

The method 600 also includes, responsive to detecting the operation, performing a comparison between a random number and at least one value of a set of values, at 604. The set of values may include multiple values or the set of values includes fewer than two values (i.e., a single value).

The method 600 further includes selectively adjusting a value of a counter associated with the block based on the comparison, at 606. For example, the counter may be adjusted when the random number matches a value of the set of values. As another example, when the set of values includes a single value, the single value may be a threshold value and the counter may be adjusted when the random number satisfies the threshold value. To illustrate, the counter may be adjusted (e.g., incremented or decremented) when the random number is greater than or equal to the threshold value. Alternatively, the counter may be adjusted (e.g., incremented or decremented) when the random number is less than or equal to the threshold value. As another example, the set of values may include two values that define a threshold range and the counter may be adjusted (e.g., incremented or decremented) when the random number matches a value within the threshold range. Alternatively, the counter may be adjusted (e.g., incremented or decremented) when the random number is outside of the threshold range.

In some implementations, a mode associated with the block may be identified. For example, the mode may be identified based on detection of the operation. As another example, the mode may be identified based on a command associated with the operation being received. The mode may include a single-level cell (SLC) mode or a multi-level cell (MLC) mode.

The random number may be generated to be constrained within a range and the range may be selected based on the mode, such as described with reference to FIG. 3. To illustrate, when the block is determined to be operating in the SLC mode, the random number may be generated to be constrained within a first range and, when the block is determined to be operating in the MLC mode, the random number may be generated to be constrained within a second range. The first range may be smaller than the second range.

Additionally or alternatively, the set of values may be selected based on the mode, such as described with reference to FIG. 5. For example, a first set of values or a second set of values may be selected to be used as the set of values. To illustrate, the first set of values is selected when the block is operating in the SLC mode, and the second set of values is selected when the block is operating in the MLC mode. The first set of values may include fewer values than second set of values.

Thus, the method 600 may track a number of program/erase cycles corresponding to the block using a statistical technique where a probability of adjusting the counter value is set based on the range of random numbers that can be generated and/or based on the set of values. Using the statistical technique, the counter value may reflect a fraction of a total number of program/erase cycles associated with the block and may be used to approximate the total number of program/erase cycles. By using the statistical technique, the counter value may be used to approximate the total number of program/erase cycles corresponding to the block without having to account for (e.g., track) each and every program/erase cycle corresponding to the block. Accordingly, a size of the counter corresponding to the block may be smaller as compared to a counter in a system that maintains (e.g., tracks) an actual number of program/erase cycle associated with the block.

The method 200 of FIG. 2, the method 300 of FIG. 3, the method 400 of FIG. 4, the method 500 of FIG. 5, and/or the method 600 of FIG. 6 may be initiated or controlled by an application-specific integrated circuit (ASIC), a processing unit, such as a central processing unit (CPU), a digital signal processor (DSP), a controller, another hardware device, a firmware device, a field-programmable gate array (FPGA) device, or any combination thereof. As an example, the method 200 of FIG. 2, the method 300 of FIG. 3, the method 400 of FIG. 4, the method 500 of FIG. 5, and/or the method 600 of FIG. 6 can be initiated or controlled by one or more processors, such as one or more processors included in or coupled to a controller or a memory of the data storage device 102 and/or the host device 130 of FIG. 1. A controller configured to perform the method 200 of FIG. 2, the method 300 of FIG. 3, the method 400 of FIG. 4, the method 500 of FIG. 5, and/or the method 600 of FIG. 6 may be able to selectively adjust a counter based on randomly generated numbers.

In an illustrative example, a processor may execute instructions that are stored at a memory to count (e.g., track) a number of program/erase cycles. For example, the processor may execute the instructions to trigger a random number generator to produce a random number value and to compare the random number value to a value of zero. The processor may further execute the instructions to, in response to the random number value being equal to zero, initiate a signal to a count input of a counter circuit to increment a counter value or, in response to the random number value not being equal to zero, to not increment the counter value.

Although various components of the data storage device 102 and the host device 130 of FIG. 1 are depicted herein are illustrated as block components and described in general terms, such components may include one or more microprocessors, state machines, or other circuits configured to enable the various components to perform operations described herein. One or more aspects of the various components may be implemented using a microprocessor or microcontroller programmed to perform operations described herein, such as one or more operations of the method 200 of FIG. 2, the method 300 of FIG. 3, the method 400 of FIG. 4, the method 500 of FIG. 5, and/or the method 600 of FIG. 6. In a particular implementation, each of the controller 120, the memory 104, and/or the host 130 of FIG. 1 includes a processor executing instructions that are stored at a memory, such as a non-volatile memory of the data storage device 102 or the host device 130. Alternatively or additionally, executable instructions that are executed by the processor may be stored at a separate memory location that is not part of the non-volatile memory, such as at a read-only memory (ROM) of the data storage device 102 or the host device 130 of FIG. 1.

In an illustrative example, the processor may execute the instructions to detect an operation associated with a block of a memory. For example, the memory may include or correspond to the memory 104 of FIG. 1. The block may include one of the blocks 152-156. The operation may be associated with a program/erase cycle. The instructions to detect an operation associated with the block may include instructions to receive a command associated with the operation (e.g., a write command or an erase command), instructions to identify the operation as a write operation or an erase operation, instructions to identify the block based on the command, instructions to execute the operation, and/or instruction to identify when execution of the operation is complete, as illustrative, non-limiting examples.

The processor may further execute the instructions to, responsive to detecting the operation, perform a comparison between a random number and at least one value of a set of value. The instructions to perform the comparison may include instructions to identify that the operation is being performed, instructions to identify when execution of the operation is completed, instructions to compare the random number to each value included in the set of values, instructions to compare the random number to one or more numbers included in the set of values until a match is identified, and/or instructions to compare the random number to a threshold value or a threshold range based on the set of values, as illustrative, non-limiting examples.

The processor may further execute the instructions to selectively adjust a value of a counter associated with the block based on the comparison. The instructions to selectively adjust the value of the counter may include instructions to identify a result of the comparison, instructions to increment the value of the counter, and/or instructions to decrement the value of the counter, as illustrative, non-limiting examples.

Semiconductor memory devices, such as the memory 104 of FIG. 1 may include volatile memory devices, such as dynamic random access memory (“DRAM”) or static random access memory (“SRAM”) devices, non-volatile memory devices, such as magnetoresistive random access memory (“MRAM”), resistive random access memory (“ReRAM”), electrically erasable programmable read only memory (“EEPROM”), flash memory (which can also be considered a subset of EEPROM), ferroelectric random access memory (“FRAM”), and other semiconductor elements capable of storing information. Each type of memory device may have different configurations. For example, flash memory devices may be configured in a NAND or a NOR configuration.

The memory devices can be formed from passive and/or active elements, in any combinations. By way of non-limiting example, passive semiconductor memory elements include ReRAM device elements, which in some embodiments include a resistivity switching storage element, such as an anti-fuse, phase change material, etc., and optionally a steering element, such as a diode, etc. Further by way of non-limiting example, active semiconductor memory elements include EEPROM and flash memory device elements, which in some embodiments include elements containing a charge storage region, such as a floating gate, conductive nanoparticles or a charge storage dielectric material.

Multiple memory elements may be configured so that they are connected in series or so that each element is individually accessible. By way of non-limiting example, flash memory devices in a NAND configuration (NAND memory) typically contain memory elements connected in series. A NAND memory array may be configured so that the array is composed of multiple strings of memory in which a string is composed of multiple memory elements sharing a single bit line and accessed as a group. Alternatively, memory elements may be configured so that each element is individually accessible, e.g., in a NOR memory array. NAND and NOR memory configurations described have been presented as examples, and memory elements may be otherwise configured.

The semiconductor memory elements located within and/or over a substrate may be arranged in two or three dimensions, such as a two dimensional memory structure or a three dimensional memory structure.

In a two dimensional memory structure, the semiconductor memory elements are arranged in a single plane or a single memory device level. Typically, in a two dimensional memory structure, memory elements are arranged in a plane (e.g., in an x-z direction plane) which extends substantially parallel to a major surface of a substrate that supports the memory elements. The substrate may be a wafer over or in which the layer of the memory elements are formed or it may be a carrier substrate which is attached to the memory elements after they are formed. As a non-limiting example, the substrate may include a semiconductor material, such as silicon.

The memory elements may be arranged in the single memory device level in an ordered array, such as in a plurality of rows and/or columns. However, the memory elements may be arranged in non-regular or non-orthogonal configurations. The memory elements may each have two or more electrodes or contact lines, such as bit lines and wordlines.

A three dimensional memory array is arranged so that memory elements occupy multiple planes or multiple memory device levels, thereby forming a structure in three dimensions (i.e., in the x, y and z directions, where the y direction is substantially perpendicular and the x and z directions are substantially parallel to the major surface of the substrate).

As a non-limiting example, a three dimensional memory structure may be vertically arranged as a stack of multiple two dimensional memory device levels. As another non-limiting example, a three dimensional memory array may be arranged as multiple vertical columns (e.g., columns extending substantially perpendicular to the major surface of the substrate, i.e., in the y direction) with each column having multiple memory elements in each column. The columns may be arranged in a two dimensional configuration (e.g., in an x-z plane), resulting in a three dimensional arrangement of memory elements with elements arranged on multiple vertically stacked memory planes. Other configurations of memory elements in three dimensions can also constitute a three dimensional memory array.

By way of non-limiting example, in a three dimensional NAND memory array, the memory elements may be coupled together to form a NAND string within a single horizontal (e.g., x-z) memory device level. Alternatively, the memory elements may be coupled together to form a vertical NAND string that traverses across multiple horizontal memory device levels. Other three dimensional configurations can be envisioned wherein some NAND strings contain memory elements in a single memory level while other strings contain memory elements which span multiple memory levels. Three dimensional memory arrays may also be designed in a NOR configuration and in a ReRAM configuration.

Typically, in a monolithic three dimensional memory array, one or more memory device levels are formed above a single substrate. Optionally, the monolithic three dimensional memory array may also have one or more memory layers at least partially within the single substrate. As a non-limiting example, the substrate may include a semiconductor material, such as silicon. In a monolithic three dimensional array, the layers constituting each memory device level of the array are typically formed on the layers of the underlying memory device levels of the array. However, layers of adjacent memory device levels of a monolithic three dimensional memory array may be shared or have intervening layers between memory device levels.

Two dimensional arrays may be formed separately and then packaged together to form a non-monolithic memory device having multiple layers of memory. For example, non-monolithic stacked memories can be constructed by forming memory levels on separate substrates and then stacking the memory levels atop each other. To illustrate, each of the memory device levels may have a corresponding substrate thinned or removed before stacking the memory device levels to form memory arrays. Because each of the memory device levels are initially formed over separate substrates, the resulting memory arrays are not monolithic three dimensional memory arrays. Further, multiple two dimensional memory arrays or three dimensional memory arrays (monolithic or non-monolithic) may be formed on separate chips and then packaged together to form a stacked-chip memory device.

In some implementations, the memory 104 (e.g., the block 152, the block 154, and/or the block 156) of FIG. 1 is a non-volatile memory having a three-dimensional (3D) memory configuration that is monolithically formed in one or more physical levels of arrays of memory cells having an active area disposed above a silicon substrate. The active area of a memory cell may be an area of the memory cell that is conductively throttled by a charge trap portion of the memory cell. The data storage device 102 and/or the host device 130 of FIG. 1 may include circuitry, such as read/write circuitry, as an illustrative, non-limiting example, associated with operation of the memory cells.

Associated circuitry is typically used for operation of the memory elements and for communication with the memory elements. As non-limiting examples, memory devices may have circuitry for controlling and driving memory elements to perform functions such as programming and reading. The associated circuitry may be on the same substrate as the memory elements and/or on a separate substrate. For example, a controller for memory read-write operations may be located on a separate controller chip and/or on the same substrate as the memory elements

One of skill in the art will recognize that this disclosure is not limited to the two dimensional and three dimensional structures described but cover all relevant memory structures within the spirit and scope of the disclosure as described herein and as understood by one of skill in the art.

The Abstract of the Disclosure is submitted with the understanding that it will not be used to interpret or limit the scope or meaning of the claims. In addition, in the foregoing Detailed Description, various features may be grouped together or described in a single embodiment for the purpose of streamlining the disclosure. This disclosure is not to be interpreted as reflecting an intention that the claimed embodiments require more features than are expressly recited in each claim. Rather, as the following claims reflect, inventive subject matter may be directed to less than all of the features of any of the disclosed embodiments.

The illustrations of the embodiments described herein are intended to provide a general understanding of the various embodiments. Other embodiments may be utilized and derived from the disclosure, such that structural and logical substitutions and changes may be made without departing from the scope of the disclosure. This disclosure is intended to cover any and all subsequent adaptations or variations of various embodiments.

The above-disclosed subject matter is to be considered illustrative, and not restrictive, and the appended claims are intended to cover all such modifications, enhancements, and other embodiments, which fall within the scope of the present disclosure. Thus, to the maximum extent allowed by law, the scope of the present disclosure is to be determined by the broadest permissible interpretation of the following claims and their equivalents, and shall not be restricted or limited by the foregoing detailed description.

What is claimed is:

1. A method comprising:
in a data storage device that includes a memory, performing
detecting an operation associated with a block of the memory, the operation associated with a program/erase cycle;
responsive to detecting the operation, performing a comparison between a random number and at least one value of a set of values; and
selectively adjusting a value of a counter associated with the block based on the comparison.

2. The method of claim 1, wherein the counter is configured to track a portion of a total number of program/erase cycles by selectively adjusting the value of the counter based on generated random numbers.

3. The method of claim 1, wherein the operation is a write operation or an erase operation.

4. The method of claim 1, further comprising identifying a mode associated with the block.

5. The method of claim 4, wherein the mode is a single-level cell (SLC) mode or a multi-level cell (MLC) mode.

6. The method of claim 4, wherein the random number is generated to be constrained within a range, and wherein the range is selected based on the mode.

7. The method of claim 4, further comprising selecting the set of values based on the mode.

8. The method of claim 1, wherein the value of the counter is adjusted when the random number matches a value of the set of values.

9. The method of claim 1, wherein the set of values includes multiple values.

10. The method of claim 1, wherein the set of values includes fewer than two values.

11. The method of claim 10, wherein set of values includes a single value that is a threshold value, and wherein the counter is adjusted when the random number satisfies the threshold value.

12. The method of claim 1, wherein the memory is a flash memory.

13. The method of claim 1, wherein the memory includes a resistive random access memory (ReRAM).

14. The method of claim 1, wherein the memory includes a three-dimensional (3D) memory configuration that is monolithically formed in one or more physical levels of arrays of memory cells having an active area disposed above a silicon substrate, and wherein the data storage device includes circuitry associated with operation of the memory cells.

15. A data storage device comprising:
a memory including a block, wherein the block is associated with a counter; and
a controller coupled to the memory, wherein the controller is configured to detect an operation associated with the block, wherein the operation is associated with a program/erase cycle, and wherein, responsive to detecting the operation, the controller is configured to perform a comparison between a random number and at least one value of a set of values and to adjust a value of the counter based on the comparison.

16. The data storage device of claim 15, wherein the controller is configured to identify whether the block is operating in a single-level cell (SLC) mode or a multi-level cell (MLC) mode.

17. The data storage device of claim 16, wherein, when the block is operating in the SLC mode, the random number is generated to be constrained within a first range, and wherein, when the block is operating in the MLC mode, the random number is generated to be constrained within a second range.

18. The data storage device of claim 17, wherein the first range is larger than the second range.

19. The data storage device of claim 16, wherein the controller is configured to select a first set of values or a second set of values to be used as the set of values, wherein the first set of values is selected when the block is operating in the SLC mode, and wherein the second set of values is selected when the block is operating in the MLC mode.

20. The data storage device of claim 19, wherein the first set of values includes more values than second set of values.

21. The data storage device of claim 15, wherein the memory includes a resistive random access memory (ReRAM).

22. The data storage device of claim 15, wherein the memory includes a three-dimensional (3D) memory configuration that is monolithically formed in one or more physical levels of arrays of memory cells having an active area disposed above a silicon substrate, and wherein the memory includes circuitry associated with operation of the memory cells.

23. A data storage device comprising:
a memory including a block, wherein the block is associated with a counter; and
a controller coupled to the memory, wherein the controller is configured to detect an operation associated with the block, wherein the operation is associated with a program/erase cycle, and wherein, responsive to detecting the operation, the controller is configured to perform a comparison between a random number and at least one value of a set of values and to adjust a value of the counter based on the comparison,
wherein the random number is constrained within a first range when the block is operating in a single-level cell (SLC) mode and wherein the random number is constrained within a second range when the block is operating in a multi-level cell (MLC) mode, and wherein the first range is larger than the second range.

24. The data storage device of claim 23, wherein the memory includes a flash memory.

25. The data storage device of claim 23, wherein the memory includes a resistive random access memory (ReRAM).

26. A data storage device comprising:
a memory including a block, wherein the block is associated with a counter; and
a controller coupled to the memory, wherein the controller is configured to detect an operation associated with the block, wherein the operation is associated with a program/erase cycle, and wherein, responsive to detecting the operation, the controller is configured to perform a comparison between a random number and at least one value of a set of values and to adjust a value of the counter based on the comparison,
wherein the set of values is a first set of values when the block is operating in a single-level cell (SLC) mode and wherein the set of values is a second set of values when the block is operating in a multi-level cell (MLC) mode, and wherein the first set of values includes more values than the second set of values.

27. The data storage device of claim 26, wherein the memory includes a flash memory.

28. The data storage device of claim 26, wherein the memory includes a resistive random access memory (ReRAM).
